(19) United States
(12) Patent Application Publication
(10) Pub. No.: US 2026/0153558 A1
(43) Pub. Date: Jun. 4, 2026

(54) METHOD FOR DETECTING DEVICES MOUNTED ON A BASEBOARD

(71) Applicant: Jabil Circuit (Singapore) Pte. Ltd., Singapore (SG)

(72) Inventors: Shih-Chuan Lei, Taichung City (TW); Jia-Cing Chen, Taichung City (TW)

(73) Assignee: Jabil Circuit (Singapore) Pte. Ltd., Singapore (SG)

(21) Appl. No.: 19/341,532

(22) Filed: Sep. 26, 2025

(30) Foreign Application Priority Data
Dec. 4, 2024 (CN) 202411773334.2

(51) Int. Cl. G01R 31/28

(52) U.S. Cl. CPC G01R 31/2843; G01R 31/2837

(57) ABSTRACT

A method for detecting a status of a to-be-detected device that is mounted on a baseboard is implemented by a baseboard management controller (BMC) module and includes: determining whether the to-be-detected device is connected under at least one layer of multiplexer (MUX); in the case that the to-be-detected device is connected under at least one layer of MUX, activating a channel for the least one layer of MUX, so as to establish a connection between the BMC module and the to-be-detected device; transmitting a test request to the to-be-detected device; determining whether a response to the test request is received from the to-be-detected device; and in the case that a response to the test request is received from the to-be-detected device, determining that the to-be-detected device is in a normal status and is functioning normally.

### CROSS-REFERENCE TO RELATED APPLICATION

This application claims priority to Chinese Invention Patent Application No. 202411773334.2, filed on Dec. 4, 2024, the entire disclosure of which is incorporated by reference herein.

### FIELD

The disclosure relates to a method for detecting a status of a device, and more particularly to a method for detecting a status of a device that is mounted on a baseboard.

### BACKGROUND

Typically, a baseboard management controller (BMC), which is an independent controlling device mounted on a baseboard (also known in some cases as a motherboard) of a server, operates independently from an operating system (OS) executed by the baseboard, and includes a network card that enables communication with a management network associated with the server. In use, the BMC is configured to detect various abnormal occurrences, and to output an alert to notify an operator of the server, so as to prevent issues that are attributed to hardware malfunction such as data loss, server outages, etc. This serves to improve reliability of the server.

It is noted that being able to identify hardware components that are not working properly in different stages of product development, particularly in earlier stages such as an engineering validation test (EVT) stage and/or a design validation test (DVT) stage, will greatly reduce the burdens for debugging on the BMC.

### SUMMARY

Therefore, an object of the disclosure is to provide a method for detecting a status of a device that is mounted on a baseboard that can be implemented in early stages of product development.

According to one embodiment of the disclosure, the method is for detecting a status of a to-be-detected device that is mounted on a baseboard. The method is implemented by a baseboard management controller (BMC) module that is electrically connected to the to-be-detected device. The method includes:
(A) determining whether the to-be-detected device is connected under at least one layer of multiplexer (MUX);
(B) in the case that the to-be-detected device is connected under at least one layer of MUX, activating a channel for the at least one layer of MUX, so as to establish a connection between the BMC module and the to-be-detected device;
(C) transmitting a test request to the to-be-detected device;
(D) determining whether a response to the test request is received from the to-be-detected device; and
(E) in the case that a response to the test request is received from the to-be-detected device, determining that the to-be-detected device is in a normal status and is functioning normally.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a baseboard management controller (BMC) module connected to a plurality of to-be-detected devices according to one embodiment of the disclosure.

FIG. 2 is a flow chart illustrating steps of an exemplary channel link information obtaining process of the method for detecting a status of a device that is mounted on a baseboard according to one embodiment of the disclosure.

FIG. 3 is a flow chart illustrating steps of an exemplary device detection process of the method for detecting a status of a device that is mounted on a baseboard according to one embodiment of the disclosure.

FIG. 4 is a flow chart illustrating sub-steps of determining whether there exists a target device dataset that is associated with a target device according to one embodiment of the disclosure.

FIG. 5 is a block diagram illustrating an exemplary configuration of the BMC module being connected to a number of to-be-detected devices according to one embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

Throughout the disclosure, the term “coupled to” or “connected to” may refer to a direct connection among a plurality of electrical apparatus/devices/equipment via an electrically conductive material (e.g., an electrical wire), or an indirect connection between two electrical apparatus/devices/equipment via another one or more apparatus/devices/equipment, or wireless communication.

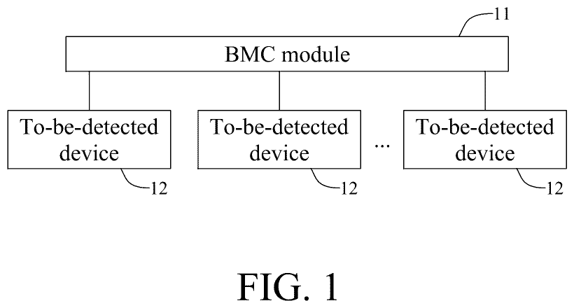

FIG. 1 is a block diagram illustrating a baseboard management controller (BMC) module 11 that is connected to a plurality of to-be-detected devices 12 mounted on a baseboard (not shown) according to one embodiment of the disclosure. In the embodiment of FIG. 1, the BMC module 11 may be embodied using a BMC that is mounted on the baseboard where the to-be-detected devices 12 are mounted, but may be embodied using other suitable electronic components in other embodiments.

Generally, the BMC module 11 may include a processing unit and a data storage unit. The data storage unit may store software instructions that, when executed by the processing unit, causes the processing unit to implement the operations as described below.

It is noted in the embodiment of FIG. 1, each of the to-be-detected devices 12 may be a bus, a device directly connected to a bus, or a device connected through one or more MUXes (multiplexers).

The BMC module 11 stores a plurality of device datasets associated with the to-be-detected devices 12, respectively. For each of the to-be-detected devices 12, the device dataset associated therewith includes an identifying index value that is an unique identifier for identifying the to-be-detected device 12, a device name of the to-be-detected device 12, a chipset serial number that indicates a chipset used by the to-be-detected device 12, a location value that indicates a descriptive location of the to-be-detected device 12, an address value that indicates an Inter-Integrated Circuit (I²C) address of the to-be-detected device 12, a level value that indicates a designated layer of the to-be-detected device 12, a parent node index number that indicates an identifying index value of a parent node connected to the to-be-detected device 12, a channel count value that indicates a number of channels on a MUX that is available for switching and that is associated with the corresponding one of the to-be-detected devices 12, a channel index value that indicates a specific channel of a multiplexer (MUX) to which the to-be-detected device 12 is connected, and an ancestor node index number that indicates a bus connected to the to-be-detected device 12.

In some embodiments, each of the plurality of device datasets compiles with the following conditions: (1) the level value is set to 1 in a case that the corresponding one of the to-be-detected devices 12 is a bus; (2) the level value is set to 2 in a case that the corresponding one of the to-be-detected devices 12 is directly connected to the bus (i.e., not connected via the MUX); (3) in a case that the corresponding one of the to-be-detected devices 12 is connected under a number N of MUXes (N≥1) in series, the corresponding one of the to-be-detected devices 12 is said to be connected under a number N layers of MUXes, and the level value is set to N+2 (for example, when a to-be-detected device 12 is connected under 2 MUXes in series, the to-be-detected device 12 is said to be connected under two layers of MUXes, and the level value of the to-be-detected device 12 is set to 4); (4) in a case that the corresponding one of the to-be-detected devices 12 is a MUX, the channel count value is obtained by determining a number of channels available for switching; (5) for each of the to-be-detected devices 12 with the level value≥3, the associated channel index value (which indicates specific channel of a multiplexer (MUX) to which the corresponding one of the to-be-detected devices 12 is connected) is pre-designated; (6) for the to-be-detected devices 12 with the level value of 2 and the same ancestor node index number (i.e., the to-be-detected devices 12 directly connected to the same bus), the to-be-detected devices 12 are assigned respectively with unique identifying index values in natural numbers and in an incrementing manner (e.g., 1, 2, 3, etc.); and (7) for the to-be-detected devices 12 with the level value of ≥3 and the same ancestor node index number and the same channel index value (i.e., the to-be-detected devices 12 directly connected to the same bus through the same channel of a MUX), the to-be-detected devices 12 are assigned respectively with unique identifying index values in natural numbers and in an incrementing manner (e.g., 1, 2, 3, etc.).

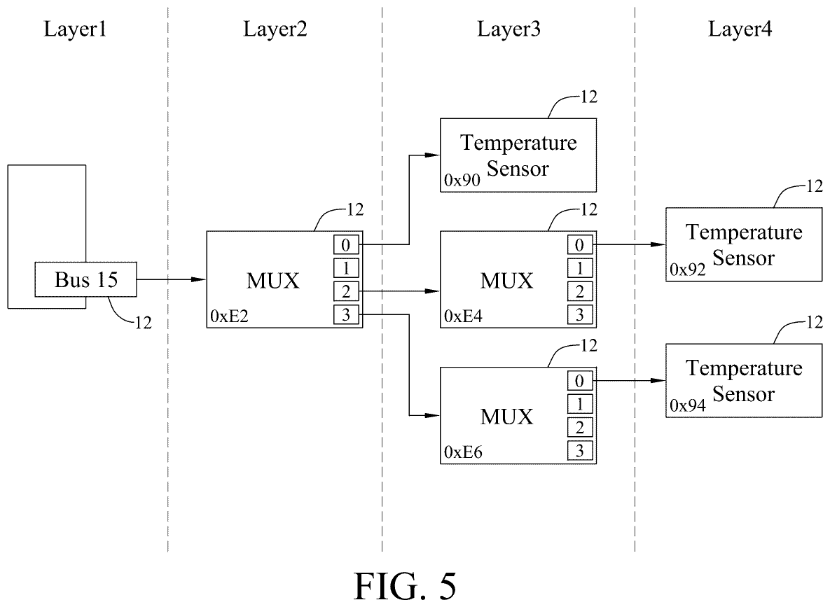

FIG. 5 is a block diagram illustrating an exemplary configuration of the BMC module 11 being connected to a number of to-be-detected devices 12 according to one embodiment of the disclosure, wherein temperature sensors are connected to the BMC through MUXes and a bus. In the embodiment of FIG. 5, a total of seven to-be-detected devices 12 are present, and each of the to-be-detected devices 12 may be a temperature sensor, a MUX (specifically, a 4-to-1 MUX), or a bus. The temperature sensors may be connected to the bus via one or more MUXes.

The following Tables 1 and 2 illustrate seven device datasets that correspond with the seven to-be-detected devices 12 shown in FIG. 5, respectively.

TABLE 1

| | | | Chipset | | Ancestor | Parent |
|---|---|---|---|---|---|---|
| Level | Identifying | Device | serial | Address | node index | node index |
| value | index value | Name | number | value | number | number |
| 1 | 15 | Bus | NULL | NULL | NULL | 0 |
| 2 | 1 | MUX | PCA9546 | HPM_U56 | 15 | 15 |
| 3 | 1 | Temperature | LM75BDP | HPM_U46 | 15 | 1 |
| | | sensor | | | | |
| 3 | 2 | MUX | PCA9546 | HPM_U58 | 15 | 1 |
| 3 | 3 | MUX | PCA9546 | HPM_U57 | 15 | 1 |
| 4 | 1 | Temperature | LM75BDP | HPM_U47 | 15 | 2 |
| | | sensor | | | | |
| 4 | 2 | Temperature | LM75BDP | HPM_U48 | 15 | 3 |
| | | sensor | | | | |

TABLE 2

| Address value | Channel count value | Channel index value |
|---|---|---|
| NULL | NULL | NULL |
| 0xe2 | 4 | NULL |
| 0x90 | NULL | 0 |
| 0xe4 | 4 | 2 |
| 0xe6 | 4 | 3 |
| 0x92 | NULL | 0 |
| 0x94 | NULL | 0 |

It is noted that three of the to-be-detected devices 12 have the same level value of 3 and the same parent node index number, meaning that the three of the to-be-detected devices 12 are connected to the bus via the same MUX. As such, the identifying index value for the three of the to-be-detected devices 12 are designated as 1, 2, and 3, respectively. For the two of the to-be-detected devices 12 that have the same level value of 4, the parent node index number is the identifying index value of the parent node (i.e., the MUXes with the level value of 3). It is noted that in the case of the bus which is considered as being at a top layer, the associated chipset serial number, the address value, the ancestor node index number, the address value, the channel count value and the channel index value are all designated as NULL. In the case of the MUX that is directly connected to the bus, the associated channel index value is designated using the NULL value. In the case of the temperature sensors, the associated channel count value is designated as NULL.

In some embodiments, there is provided a method for detecting a status of a device that is mounted on a baseboard. In some embodiments, the method for detecting a status of a device that is mounted on a baseboard includes a channel link information obtaining process and a device detection process.

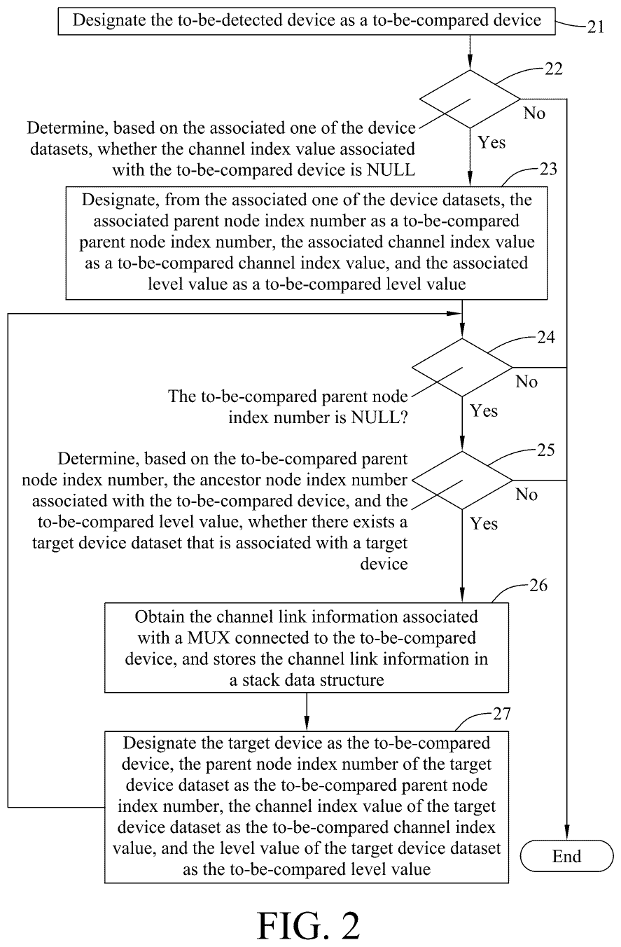

FIG. 2 is a flow chart illustrating steps of an exemplary channel link information obtaining process of the method for detecting a status of a device that is mounted on a baseboard according to one embodiment of the disclosure. The channel link information obtaining process is for obtaining channel link information associated with a MUX connected to one of the to-be-detected devices 12. In this embodiment, the channel link information obtaining process is implemented using the BMC module 11 of FIG. 1. It is noted that since the details of obtaining the channel link information for each of the to-be-detected devices 12 is similar, in the following paragraphs, the operations described are with respect to a single to-be-detected device 12. In general, the channel link information obtaining process may be implemented with respect to each of the to-be-detected devices 12 individually.

In step 21, the BMC module 11 designates the to-be-detected device 12 as a to-be-compared device.

In step 22, the BMC module 11 determines, based on the associated one of the device datasets, whether the channel index value associated with the to-be-compared device is NULL. In the case that it is determined that the channel index value associated with the to-be-compared device is NULL, the channel link information obtaining process is terminated (as there is no channel link information to obtain), and the BMC module 11 may initiate the channel link information obtaining process for another one of the to-be-detected devices 12. On the other hand, in the case that the channel index value associated with the to-be-compared device is not NULL, the flow proceeds to step 23.

In step 23, the BMC module 11 designates, from the associated one of the device datasets, the associated parent node index number as a to-be-compared parent node index number, the associated channel index value as a to-be-compared channel index value, and the associated level value as a to-be-compared level value.

In step 24, the BMC module 11 determines whether the to-be-compared parent node index number is NULL. In the case that it is determined that the to-be-compared parent node index number is NULL, the channel link information obtaining process is terminated, and the BMC module 11 may initiate the channel link information obtaining process for another one of the to-be-detected devices 12. On the other hand, in the case that the to-be-compared parent node index number is not NULL, the flow proceeds to step 25.

In step 25, the BMC module 11 determines, based on the to-be-compared parent node index number, the ancestor node index number associated with the to-be-compared device, and the to-be-compared level value, whether there exists a target device dataset that is associated with a target device (that is, one of the to-be-detected devices 12 that is connected to the to-be-compared device as a parent node). In the case that it is determined that the target device dataset does not exist, the channel link information obtaining process is terminated, and the BMC module 11 may initiate the channel link information obtaining process for another one of the to-be-detected devices 12. On the other hand, in the case that it is determined that there exists at least one target device dataset, the flow proceeds to step 26.

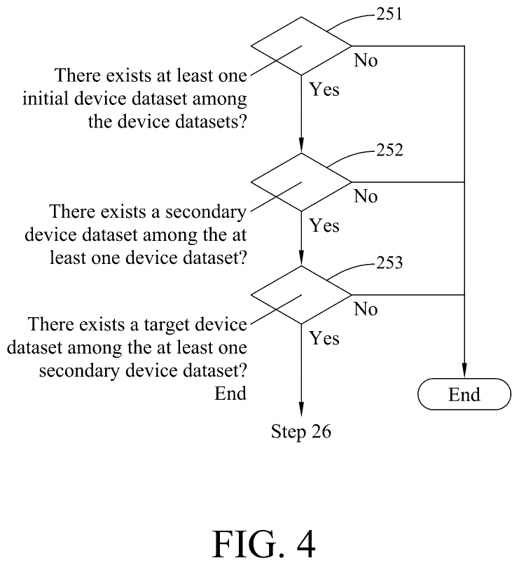

Specifically, FIG. 4 is a flow chart illustrating sub-steps of step 25 according to one embodiment of the disclosure.

In sub-step 251, the BMC module 11 determines whether there exists at least one initial device dataset among the device datasets. Specifically, the initial device dataset is defined as one of the device datasets that has an ancestor node index number identical to the ancestor node index number of the to-be-compared device. In the case that it is determined that the initial device dataset does not exist, the channel link information obtaining process is terminated. On the other hand, in the case that it is determined that there exists at least one initial device dataset, the flow proceeds to sub-step 252.

In sub-step 252, the BMC module 11 determines whether there exists a secondary device dataset among the at least one device dataset. Specifically, the secondary device dataset is defined as one of the at least one initial device dataset that has a level value equal to the layer value of the to-be-compared device minus one. In the case that it is determined that the secondary device dataset does not exist, the channel link information obtaining process is terminated. On the other hand, in the case that it is determined that there exists at least one secondary device dataset, the flow proceeds to sub-step 253.

In sub-step 253, the BMC module 11 determines whether there exists a target device dataset among the at least one secondary device dataset. Specifically, the target device dataset is defined as one of the at least one secondary device dataset that has an identifying index value identical to the parent node index number of the to-be-compared device. In the case that it is determined that the target device dataset does not exist, the channel link information obtaining process is terminated. On the other hand, in the case that it is determined that there exists a target device dataset, the flow proceeds to step 26.

In step 26, the BMC module 11 obtains the channel link information associated with a MUX connected to the to-be-compared device, and stores the channel link information in a stack data structure. Specifically, the channel link information may be obtained from the target device dataset and the device dataset of the to-be-compared device. As such, by using the stack data structure, a number of entries of channel link information may be arranged in a stack sequence. In the stack sequence, an entry of channel link information associated with a MUX having a lowest level value (e.g., 2), also said to be located in a top layer of a linking relationship of MUXes, is placed on a top of the stack data structure, and an entry of channel link information associated with a MUX having a largest level value, also said to be located in a bottom layer of the linking relationship of MUXes, is placed at a bottom of the stack data structure.

In some embodiments, one entry of channel link information may include information for identifying the MUX and information for identifying a channel that connects the MUX to the to-be-compared device (directly or via another MUX). Additionally, the information for identifying the MUX included in the entry of channel link information may be obtained based on the address value of the target device dataset, and the information for identifying the channel may be obtained based on the channel index value of the target device dataset, but the operations of step 26 is not limited to the manners as described above.

In step 27, the BMC module 11 designates the target device as the to-be-compared device, the parent node index number of the target device dataset as the to-be-compared parent node index number, the channel index value of the target device dataset as the to-be-compared channel index value, and the level value of the target device dataset as the to-be-compared level value. Then, the flow goes back to step 24 for the newly designated to-be-compared device.

Using the to-be-detected device 12 that is a temperature sensor with the address value of HPM_U48 shown in Tables 1 and 2 as an example, the channel link information obtaining process of the method may be implemented as follows.

In step 21, the BMC module 11 designates the to-be-detected device 12 that is a temperature sensor with the address value of HPM_U48 as a to-be-compared device.

In step 22, the BMC module 11 determines that the associated channel index value is zero, which is not NULL. As such, the flow proceeds to step 23, in which the BMC module 11 designates, based on the associated one of the device datasets, the associated parent node index number “3” as the to-be-compared parent node index number, the associated channel index value “0” as the to-be-compared channel index value, and the associated level value “4” as the to-be-compared level value.

In step 24, the BMC module 11 determines that the to-be-compared parent node index number is 3, which is not NULL. As such, the flow proceeds to step 25, in which the BMC module 11 determines, based on the to-be-compared parent node index number, the to-be-compared channel index value, and the to-be-compared level value, whether there exists a target device dataset that is associated with a target device.

Specifically, in sub-step 251, the BMC module 11 determines whether there exists at least one initial device dataset that has an ancestor node index number that is identical to the ancestor node index number of the to-be-compared device (i.e., 15). In this example, five initial device datasets are found.

In sub-step 252, the BMC module 11 determines, among the initial device datasets, whether there exists a secondary device dataset that has a level value equal to the layer value of the to-be-compared device minus one (i.e., 4−1=3). In this example, one secondary device dataset (associated with the MUX with the address value of HPM_U57) is found.

In sub-step 253, the BMC module 11 determines, among the secondary device dataset, whether there exists a target device dataset that has an identifying index value identical to the parent node index number of the to-be-compared device (i.e., 3). In this example, it is determined that the target device dataset does exist, and the MUX with the address value of HPM_U57 is deemed as the target device.

In step 26, the BMC module 11 obtains the channel link information associated with a MUX connected to the to-be-compared device, and stores the channel link information in the stack data structure.

In step 27, the BMC module 11 designates the target device as the to-be-compared device, the parent node index number of the target device dataset (i.e., 1) as the to-be-compared parent node index number, the channel index value of the target device dataset (i.e., 3) as the to-be-compared channel index value, and the level value of the target device dataset (i.e., 3) as the to-be-compared level value. Then, the flow goes back to step 24 for the newly designated to-be-compared device.

The BMC module 11 executes step 24 again and determines that the to-be-compared parent node index number is 1, which is not NULL. As such, the flow proceeds to step 25, in which the BMC module 11 determines, based on the to-be-compared parent node index number, the ancestor node index number associated with the to-be-compared device, and the to-be-compared level value, whether there exists a target device dataset that is associated with a target device.

Specifically, in sub-step 251, the BMC module 11 determines whether there exists at least one initial device dataset that has an ancestor node index number identical to the ancestor node index number of the to-be-compared device (i.e., 15). In this example, five initial device datasets are found.

In sub-step 252, the BMC module 11 determines, among the initial device datasets, whether there exists a secondary device dataset that has a level value equal to the layer value of the to-be-compared device minus one (i.e., 3−1=2). In this example, one secondary device dataset (associated with the MUX with the address value of HPM_U56) is found.

In sub-step 253, the BMC module 11 determines, among the secondary device dataset, whether there exists a target device dataset that has an identifying index value identical to the parent node index number of the to-be-compared device (i.e., 1). In this example, it is determined that the target device dataset does exist, and the MUX with the address value of HPM_U56 is deemed as the target device.

In step 26, the BMC module 11 obtains the channel link information associated with a MUX connected to the to-be-compared device, and stores the channel link information in the stack data structure.

In step 27, the BMC module 11 designates the target device as the to-be-compared device, the parent node index number of the target device dataset (i.e., 15) as the to-be-compared parent node index number, the channel index value of the target device dataset (i.e., NULL) as the to-be-compared channel index value, and the level value of the target device dataset (i.e., 2) as the to-be-compared level value. Then, the flow goes back to step 24 for the newly designated to-be-compared device.

The BMC module 11 will then execute step 24 to determine that the to-be-compared parent node index number is NULL. As such, the channel link information obtaining process is terminated.

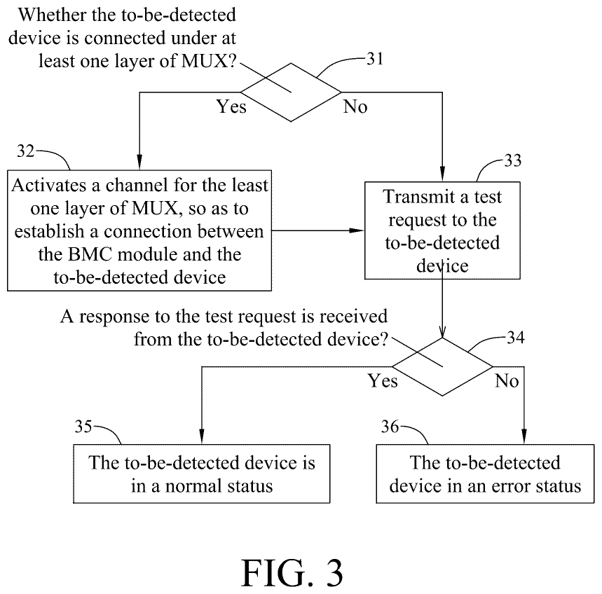

FIG. 3 is a flow chart illustrating steps of an exemplary device detection process of the method for detecting a status of a device that is mounted on a baseboard according to one embodiment of the disclosure. In this embodiment, the device detection process is implemented using the BMC module 11 of FIG. 1, and is for determining whether one of the to-be-detected devices 12 is functioning properly. It is noted that since the details of the device detection process for each of the to-be-detected devices 12 is similar, in the following paragraphs, the operations described are with respect to a single to-be-detected device 12. In general, the device detection process may be implemented with respect to each of the to-be-detected devices 12 individually.

In step 31, the BMC module 11 determines whether the to-be-detected device 12 is connected under at least one layer of MUX. Specifically, the operations of step 31 may be done by determining whether the level value of the associated one of the device datasets is greater than 2. In the case that the BMC module 11 determines that the to-be-detected device 12 is connected under at least one layer of MUX, the flow proceeds to step 32. Otherwise, in the case that the BMC module 11 determines that the to-be-detected device 12 is not connected under at least one layer of MUX, the flow proceeds to step 33.

In step 32, the BMC module 11 activates a channel for the least one layer of MUX, so as to establish a connection between the BMC module 11 and the to-be-detected device 12. Specifically, the BMC module 11 may access the top of the stack data structure by performing a pop operation on the stack data structure to obtain the channel link information, so as to activate the corresponding channel as indicated by the channel link information. It is noted that in the case that the to-be-detected device 12 is connected under a plurality of layers of MUXes, the BMC module 11 may repeatedly perform the pop operation on the stack data structure to obtain additional channel link information, in order to activate the channels for the MUX(es) that are connected in the lower layers, and to eventually establish the connection between the BMC module 11 and the to-be-detected device 12.

In step 33, the BMC module 11 transmits a test request to the to-be-detected device 12. It is noted that in the case that the to-be-detected device 12 is not connected under at least one layer of MUX, the BMC module 11 is able to transmit the test request directly to the to-be-detected device 12. On the other hand, in the case that the to-be-detected device 12 is connected under at least one layer of MUX, the BMC module 11 is able to transmit the test request to the to-be-detected device 12 using the connection established in step 31.

In step 34, the BMC module 11 determines whether a response to the test request is received from the to-be-detected device 12. In the case that a response to the test request is received from the to-be-detected device 12, the flow proceeds to step 35, in which the BMC module 11 determines that the to-be-detected device 12 is in a normal status and is functioning normally. On the other hand, in the case that the BMC module 11 determines that no response is received from the to-be-detected device 12 (e.g., after a predetermined time period has elapsed without receiving the response to the test request), the flow proceeds to step 36, in which the BMC module 11 determines that the to-be-detected device 12 is in an error status and is not functioning normally. In some embodiments, the predetermined time period may be manually inputted by an operator as one of a plurality of setting parameters prior to implementing the method. It is noted that in the case that no predetermined time period is inputted, the flow may remain in step 35 to continue waiting for the response. In some embodiments, the BMC module 11 may generate and output an alert to notify a personnel that the to-be-detected device 12 is in the error status.

To sum up, embodiments of the disclosure provides a method for detecting a status of a device that is mounted on a baseboard. In the method, as soon as the devices are connected to the BMC module directly or through the MUX(es), the channel link information obtaining process may be first implemented to establish a stack data structure that stores the channel link information for all of the devices connected to the BMC module via at least one layer of MUX. Then, the device detection process may be implemented to determine whether each of the to-be-detected devices is functioning normally. Since the method may be implemented in different stages of product development, particularly in earlier stages such as an engineering validation test (EVT) stage and/or a design validation test (DVT) stage, the method may be very effective in reducing potential errors made in the earlier stages, therefore reducing the burden of debugging in later stages of product development.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for detecting a status of a to-be-detected device that is mounted on a baseboard, the method being implemented by a baseboard management controller (BMC) module that is electrically connected to the to-be-detected device, the method comprising steps of:
(A) determining whether the to-be-detected device is connected under at least one layer of multiplexer (MUX);
(B) in the case that the to-be-detected device is connected under at least one layer of MUX, activating a channel for the at least one layer of MUX, so as to establish a connection between the BMC module and the to-be-detected device;
(C) transmitting a test request to the to-be-detected device;
(D) determining whether a response to the test request is received from the to-be-detected device; and
(E) in the case that a response to the test request is received from the to-be-detected device, determining that the to-be-detected device is in a normal status and is functioning normally.

2. The method as claimed in claim 1, further comprising a step of:
(G) in the case that a response to the test request is not received from the to-be-detected device, determining that the to-be-detected device is in an error status and is not functioning normally.

3. The method as claimed in claim 1, wherein:
step (B) includes activating the channel based on channel link information, the channel link information includes information for identifying the MUX and information for identifying a channel that connects the MUX to the to-be-detected device.

4. The method as claimed in claim 3, the BMC module storing a stack data structure, the stack data structure storing a number of entries of channel link information arranged in a stack sequence, with an entry of channel link information associated with a MUX located in a top layer of a linking relationship of MUXes being placed on a top of the stack data structure, and an entry of channel link information associated with a MUX located in a bottom layer of the linking relationship of MUXes being placed at a bottom of the stack data structure, wherein:
step (B) further includes accessing the stack data structure to obtain the channel link information.

5. The method as claimed in claim 1, a plurality of to-be-detected devices being mounted on the baseboard and electrically connected to the BMC module, the BMC module storing a plurality of device datasets, each of the device dataset being associated with one of the plurality of to-be-detected devices, respectively, and including an identifying index value for identifying the to-be-detected device, an address value that indicates an Inter-Integrated Circuit (I²C) address of the to-be-detected device, a level value that indicates a designated layer of the to-be-detected device, a parent node index number that indicates an identifying index value of a parent node connected to the to-be-detected device, a channel index value that indicates a specific channel of a MUX to which the to-be-detected device is connected, and an ancestor node index number that indicates a bus connected to the to-be-detected devices, the method further comprising, prior to step (B), the step of:
(H) designating one of the to-be-detected devices as a to-be-compared device;
(I) determining, based on the associated one of the device datasets, whether the channel index value associated with the to-be-compared device is NULL;
(J) in the case that it is determined that the channel index value associated with the to-be-compared device is not NULL, designating, from the associated one of the device datasets, the associated parent node index number as a to-be-compared parent node index number, the associated channel index value as a to-be-compared channel index value, and the associated level value as a to-be-compared level value;
(K) determining whether the to-be-compared parent node index number is NULL;
(L) in the case that it is determined that the to-be-compared parent node index number is not NULL, determining, based on the to-be-compared parent node index number, the ancestor node index number associated with the to-be-compared device, and the to-be-compared level value, whether there exists a target device dataset that is associated with a target device that is connected to the to-be-compared device as a parent node;
(M) in the case that it is determined that there exists a target device dataset, obtaining channel link information associated with a MUX connected to the to-be-compared device from the target device dataset and the device dataset of the to-be-compared device; and
(N) designating the target device as the to-be-compared device, the parent node index number of the target device dataset as the to-be-compared parent node index number, the channel index value of the target device dataset as the to-be-compared channel index value, and the level value of the target device dataset as the to-be-compared level value, and repeating step (K) for the newly designated to-be-compared device.

6. The method as claimed in claim 5, wherein step (L) includes:
determining, among the plurality of device datasets, whether there exists at least one initial device dataset, the initial device dataset being defined as one that has an ancestor node index number that is identical to the ancestor node index number of the to-be-compared device;
in the case that it is determined that there exists at least one initial device dataset, determining, from the at least one initial device dataset, whether there exists a secondary device dataset, the initial device dataset being defined as one that has a level value that is the layer value of the to-be-compared device minus one; and
in the case that it is determined that there exists at least one secondary device dataset, determining, from the at least one secondary device dataset, whether there exists a target device dataset, the target device dataset being defined as one that has an identifying index value that is identical to the parent node index number of the to-be-compared device.

7. The method as claimed in claim 6, one entry of channel link information including information for identifying the MUX and information for identifying a channel that connects the MUX to the to-be-compared device, wherein step (M) includes obtaining the information for identifying the MUX included in the entry of channel link information based on the address value of the target device dataset, and obtaining the information for identifying the channel based on the channel index value of the target device dataset.

8. The method as claimed in claim 5, wherein step (M) includes storing the channel link information in a stack data structure.
